(19) United States
(12) Patent Application Publication
(10) Pub. No.: US 2025/0169176 A1
(43) Pub. Date: May 22, 2025

(54) SEMICONDUCTOR DEVICE WITH GROUP III-V COMPOUND MATERIAL

(71) Applicant: Monolithic Power Systems, Inc., Kirkland, WA (US)

(72) Inventors: Eric Braun, Mountain View, CA (US); James Nguyen, Bellevue, WA (US)

(21) Appl. No.: 18/512,540

(22) Filed: Nov. 17, 2023

(51) Int. Cl. H01L 27/095; H01L 21/8252; H01L 29/06; H01L 29/20; H01L 29/66; H01L 29/778; H03K 17/687

(52) U.S. Cl. CPC H10D 84/86; H03K 17/6871; H10D 30/015; H10D 30/475; H10D 62/126; H10D 62/8503; H10D 84/05

(57) ABSTRACT

A semiconductor device has a substrate, and a heterojunction structure formed by two group III-V compound layers above the substrate. A first gate electrode is deposited above a first group III-V compound layer and a second group III-V compound layer, the first gate electrode is electrically connected to a first gate terminal. A second gate electrode is deposited above the first group III-V compound layer and the second group III-V compound layer, the second gate electrode is electrically connected to a second gate terminal. A source electrode is deposited above the heterojunction structure, the source electrode is electrically connected to a source terminal. A first drain electrode deposited above the heterojunction structure, the first drain electrode is electrically connected to a drain terminal. A second drain electrode deposited above the heterojunction structure, the second drain electrode is electrically connected to the first gate terminal.

### BACKGROUND OF THE INVENTION

### 1. Field of the Invention

The present invention generally relates to semiconductor device, and more particularly but not exclusively relates to group III-V compound semiconductor device.

### 2. Description of Related Art

The group III-V compound material has wide band gap, high saturated electron rate, high thermal conductivity, so that the group III-V compound material is suitable for electronic devices with high frequency, high power, and high temperature applications. As a result, a group III-V compound device, e.g., a gallium nitride (GaN) Field Effect Transistor (FET), has attracted more and more interest for switching power supplies, due to their potentials for fast switching, low power loss, high breakdown voltage, high operating temperature, and so on.

The GaN FET has a lower threshold voltage than conventional Si based FET. However, an unwanted turn-on may occur during turn-off of the GaN FET per the lower threshold voltage, and parasitic parameters between a gate terminal of the GaN FET and a driving circuit.

### SUMMARY OF THE INVENTION

It is one of the objects of the present invention to provide a semiconductor device with group III-V compound material insensitive to noise from drive path.

One embodiment of the present invention discloses a semiconductor device, comprising a substrate, a heterojunction structure, a first gate electrode, a second gate electrode, a source electrode, a first drain electrode, and a second drain electrode. The heterojunction structure is formed by a first group III-V compound layer and a second group III-V compound layer above the substrate. The first gate electrode is deposited above the first group III-V compound layer and the second group III-V compound layer, the first gate electrode is electrically connected to a first gate terminal. The second gate electrode is deposited above the first group III-V compound layer and the second group III-V compound layer, the second gate electrode is electrically connected to a second gate terminal. The source electrode is deposited above the heterojunction structure, the source electrode is electrically connected to a source terminal. The first drain electrode is deposited above the heterojunction structure, the first drain electrode is electrically connected to a drain terminal. The second drain electrode is deposited above the heterojunction structure, the second drain electrode is electrically connected to the first gate terminal. The first gate electrode is positioned between the source electrode and the first drain electrode, and the second gate electrode is positioned between the source electrode and the second drain electrode.

Another embodiment of the present invention discloses a semiconductor device, comprising a substrate, a GaN layer and an aluminum gallium nitride (AlGaN) layer. The GaN layer is epitaxially growing above the substrate. The AlGaN layer is epitaxially growing above the GaN layer, to create a heterojunction structure. A first gate electrode and a second gate electrode are deposited above the AlGaN layer, and a length of the second gate electrode is less than a length of the first gate electrode. A source electrode, a first drain electrode and a second drain electrode are deposited above the GaN layer. The first gate electrode is positioned between the source electrode and the first drain electrode, the second gate electrode is positioned between the source electrode and the second drain electrode, and the second drain electrode is electrically connected to the first gate electrode.

Yet another embodiment of the present invention discloses a semiconductor device, comprising a first die. The first die having a substrate, a heterojunction structure formed by two group III-V compound layers on the substrate, a first field effect transistor (FET) device and a second FET device formed on the substrate. The first FET device having a source electrode and a first drain electrode deposited above the heterojunction structure, and a first gate electrode deposited above the two group III-V compound layers. The second FET device having the source electrode shared with the first FET device, a second drain electrode deposited above the heterojunction structure, and a second gate electrode deposited above the two group III-V compound layers. The second drain electrode is electrically connected to the first gate electrode.

These and other features of the present invention will be readily apparent to persons of ordinary skill in the art upon reading the entirety of this disclosure, which includes the accompanying drawings and claims.

### BRIEF DESCRIPTION OF DRAWINGS

The present invention can be further understood with reference to the following detailed description and the appended drawings, wherein like elements are provided with like reference numerals. The drawings are only for illustration purpose, thus may only show part of the devices and are not necessarily drawn to scale.

FIG. 1 illustrates a cross-sectional view of a conventional GaN field effect transistor (FET) 100.

FIG. 2 illustrates a cross-sectional view of a semiconductor device 200 with group III-V compound material in accordance with an embodiment of the present invention.

FIG. 3 illustrates a cross-sectional view of a semiconductor device 200A with group III-V compound material in accordance with an embodiment of the present invention.

FIG. 4 illustrates a cross-sectional view of a semiconductor device 200B with group III-V compound material in accordance with an embodiment of the present invention.

FIG. 5 illustrates a cross-sectional view of a semiconductor device 500 with group III-V compound material in accordance with an embodiment of the present invention.

FIG. 6A schematically illustrates a circuit block diagram 20 of the semiconductor device 500 and a driving circuit 600 in accordance with an embodiment of the present invention.

FIG. 6B schematically illustrates a semiconductor device 60 in accordance with an embodiment of the present invention.

FIG. 7 illustrates a cross-sectional view of a semiconductor device 700 with group III-V compound material in accordance with an embodiment of the present invention.

FIG. 8A schematically illustrates a circuit block diagram 30 of the semiconductor device 700 and a driving circuit 800 in accordance with an embodiment of the present invention.

FIG. 8B schematically illustrates a semiconductor device 80 in accordance with an embodiment of the present invention.

FIG. 9 illustrates a method 900 of forming a semiconductor device in accordance with an embodiment of the present invention.

### DETAILED DESCRIPTION OF THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

The terms “left,” right,” “in,” “out,” “front,” “back,” “up,” “down, “top,” “atop”, “bottom,” “over,” “under,” “beneath,” “above,” “below” and the like in the description and the claims, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein.

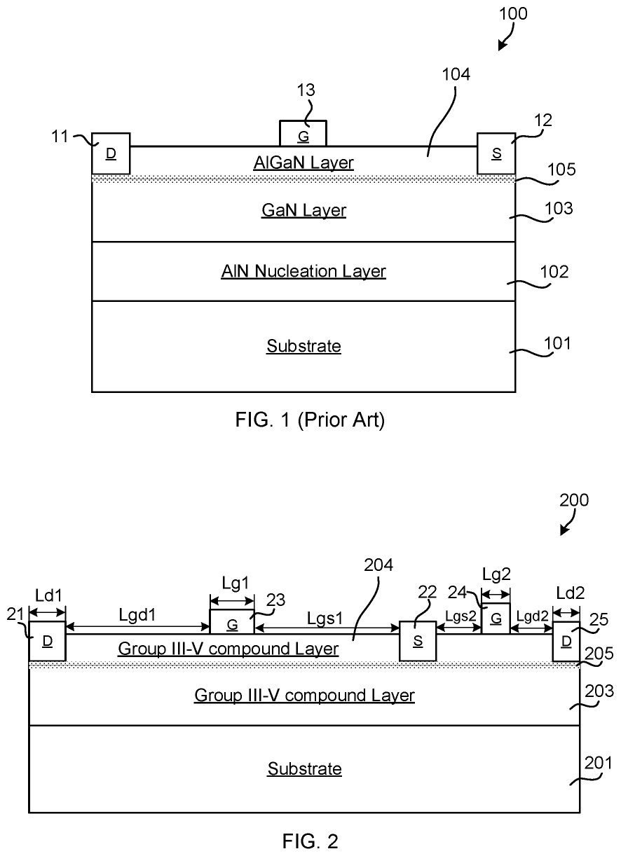

FIG. 1 illustrates a cross-sectional view of a conventional GaN field effect transistor (FET) 100. The GaN FET 100 has a substrate 101, e.g., a silicon substrate, a SiC substrate, and so on. An aluminum nitride (AlN) nucleation layer 102 is grown on the substrate 101 to provide a base layer for epitaxially growing. In FIG. 1, a GaN layer 103 is grown on the AlN nucleation layer 102 and an aluminum gallium nitride (AlGaN) layer 104 is grown on the GaN layer 103. A two-dimension electron gas (2-DEG) region 105 is formed at a transition between the GaN layer 103 and the AlGaN layer 104. A source electrode 12 and a drain electrode 11 with conductive metal are deposited above the 2-DEG region 105. A gate electrode 13 is deposited above the AlGaN layer 104, laterally located between the source electrode 12 and the drain electrode 11. The conventional GaN FET 100 has a lower threshold voltage than Si based FET, but more sensitive to a voltage applied between the drain electrode 11 and the source electrode 12, unwanted turn-on may be easily occurred caused by a voltage spike between the drain electrode 11 and the source electrode 12.

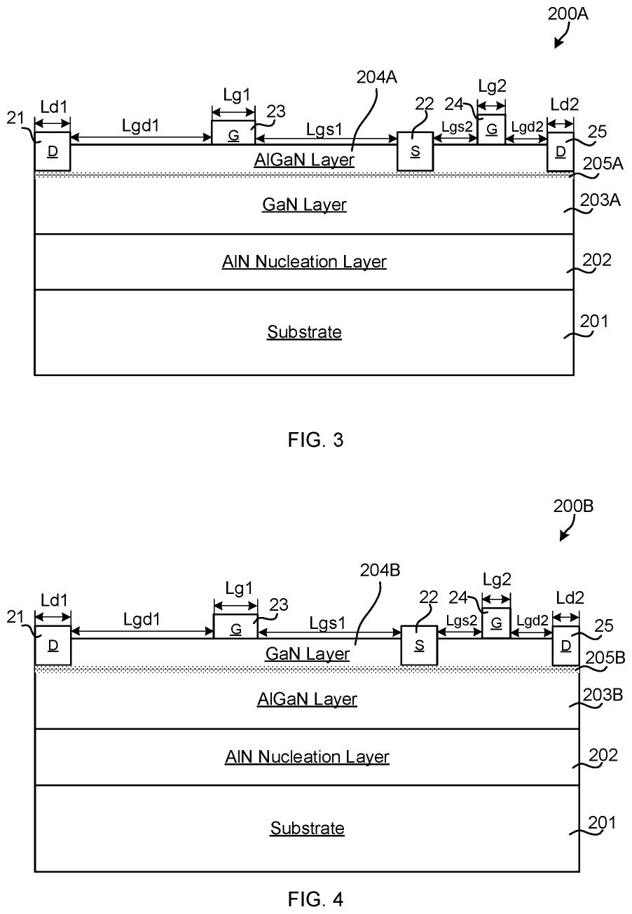

FIG. 2 illustrates a cross-sectional view of a semiconductor device 200 with group III-V compound material in accordance with an embodiment of the present invention. The semiconductor device 200 has a substrate 201, and a heterojunction structure formed on the substrate 201 to create a 2-DEG region 205. The substrate 201 may be a silicon substrate, a SiC substrate, and any other suitable substrate. The heterojunction structure is formed by two different group III-V compound layers 203 and 204. In one embodiment, the group III-V compound layer 203 is a buffer layer, such as GaN layer or a GaAs layer, and the group III-V compound layer 204 is a buried layer, such as an AlGaN layer or an AlGaAs layer. In another embodiment, the group III-V compound layer 203 is the buried layer, such as the AlGaN layer or the AlGaAs layer, and the group III-V compound layer 204 is the buffer layer, such as the GaN layer or the GaAs layer. The 2-DEG region 205 is formed at a transition between the group III-V compound layer 203 and the group III-V compound layer 204.

A source electrode 22, a drain electrode 21 and a drain electrode 25 with conductive metal are deposited on the heterojunction structure to make contact to the 2-DEG region, thus to form ohmic contacts with the 2-DEG region 205. A gate electrode 23 and a gate electrode 24 are deposited on the group III-V compound layer 204. In one embodiment, the gate electrode 23 is laterally located between the source electrode 22 and the drain electrode 21, and the gate electrode 24 is laterally located between the source electrode 22 and the drain electrode 25. In one embodiment, the semiconductor device 200 is a high electron mobility transistor (HEMT) device.

As shown in FIG. 2, the semiconductor device 200 integrates two different group III-V compound FETs on the same substrate 201. The two group III-V compound FETs share the same source electrode 22, the same group III-V compound layer 203, and the same group III-V compound layer 204, i.e., the same heterojunction structure. One of the group III-V compound FETs comprises the drain electrode 21, the source electrode 22, and the gate electrode 23. The other of the group III-V compound FETs comprises the drain electrode 25, the source electrode 22, and the gate electrode 24. The concentration of the 2-DEG region 205 between the source electrode 22 and the drain electrode 21 is controlled with a voltage applied to the gate electrode 23. In one embodiment, when the voltage applied to the gate electrode 23, a first conduction path is formed between the source electrode 22 and the drain electrode 21, the group III-V compound FET comprising the drain electrode 21, the source electrode 22 and the gate electrode 23 is turned ON. In one embodiment, when the voltage applied between the gate electrode 24 and the source electrode 22 is higher than a second threshold voltage, a second conduction path is formed between the source electrode 22 and the drain electrode 25, the group III-V compound FET comprising the drain electrode 25, the source electrode 22 and the gate electrode 24 is turned ON.

In one embodiment, the two group III-V compound FETs have different layout sizes. For example, a layout length Lg2 of the gate electrode 24 may be less than a layout length Lg1 of the gate electrode 23, a layout length Ld2 of the drain electrode 25 may be less than a layout length Ld1 of the drain electrode 21, a distance Lgd2 between the drain electrode 25 and the gate electrode 24 may be less than a distance Lgd1 between the drain electrode 21 and the gate electrode 23, and/or a distance Lgs2 between the source electrode 22 and the gate electrode 24 may be less than a distance Lgs1 between the source electrode 22 and the gate electrode 23. Such that at least two different group III-V compound FETs are integrated together, each having different dimension, and different on resistance. The semiconductor device 200 could have both fast switching and strong anti-interference ability by applied proper voltages on the gate electrode 23 and the gate electrode 24.

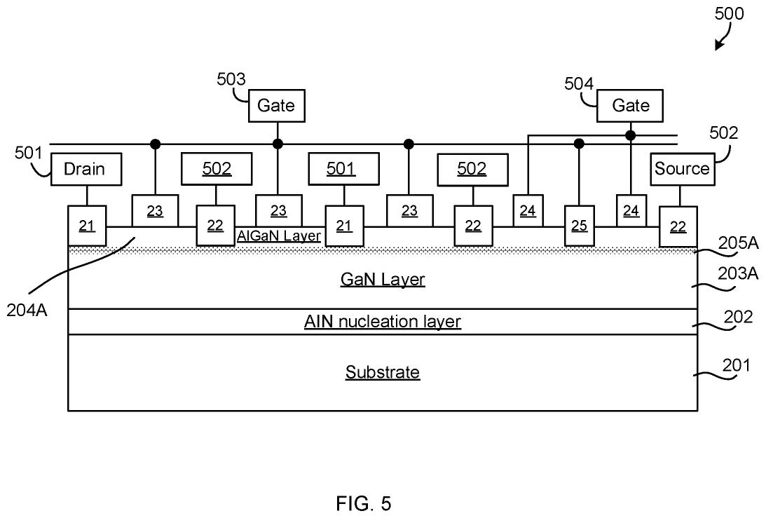

FIG. 3 illustrates a cross-sectional view of a semiconductor device 200A with group III-V compound material in accordance with an embodiment of the present invention. In one embodiment, an AlN nucleation layer 202 is formed on the substrate 201 to epitaxially grow a GaN layer 203A and an AlGaN layer 204A. In FIG. 3, the GaN layer 203A is formed on the AlN nucleation layer 202, and an AlGaN layer 204A is formed on the GaN layer 203A, to create a 2-DEG region 205A at the heterojunction structure, that is at the transition between the GaN layer 203A and the AlGaN layer 204A.

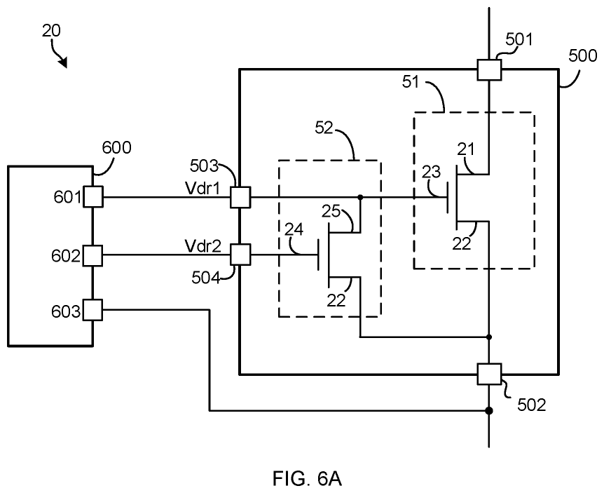

FIG. 4 illustrates a cross-sectional view of a semiconductor device 200B with group III-V compound material in accordance with an embodiment of the present invention. In FIG. 4, an AlGaN layer 203B is formed on the AlN nucleation layer 202, and a GaN layer 204B is formed on the AlGaN layer 203B, to create a 2-DEG region 205B at the heterojunction structure, that is at the transition between the AlGaN layer 203B and the GaN layer 204B.

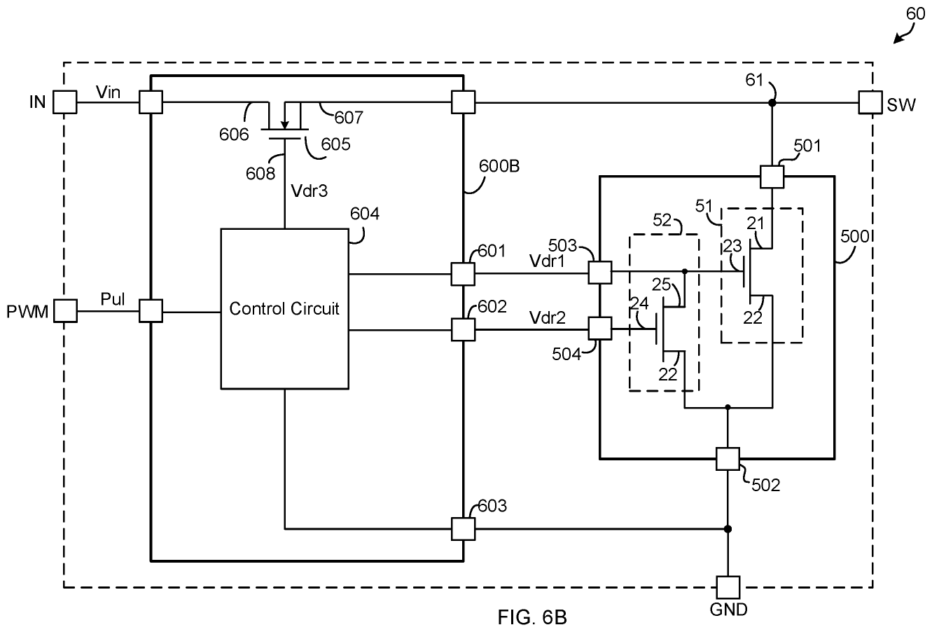

FIG. 5 illustrates a cross-sectional view of a semiconductor device 500 with group III-V compound material in accordance with an embodiment of the present invention. As shown in FIG. 5, the AlGaN layer 204A is formed on the GaN layer 203A to create the 2-DEG region 205A at the heterojunction structure as one example. People with ordinary skill in the art should also understand that the GaN layer 203A may be formed on the AlGaN layer 204A to create the 2-DEG region 205A without detracting from merits of the embodiments of the present invention.

The semiconductor device 500 further has a drain terminal 501, a source terminal 502, a gate terminal 503, and a gate terminal 504. The gate electrode 23 is electrically connected to the gate terminal 503, the gate electrode 24 is electrically connected to the gate terminal 504, the source electrode 22 is electrically connected to the source terminal 502, the drain electrode 21 is electrically connected to the drain terminal 501, and the drain electrode 25 is electrically connected to the gate electrode 503.

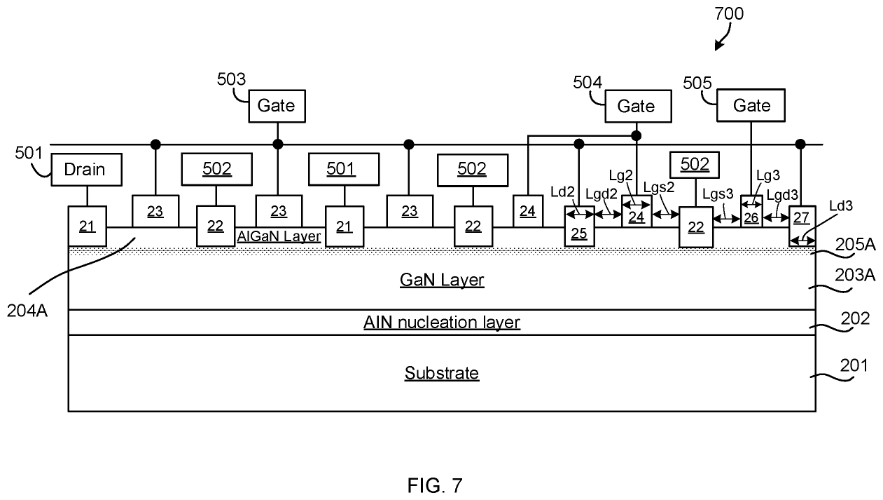

FIG. 6A schematically illustrates a circuit block diagram 20 of the semiconductor device 500 and a driving circuit 600 in accordance with an embodiment of the present invention. The semiconductor device 500 integrates a group III-V compound FET 51 and a group III-V compound FET 52. The group III-V compound FET 51 comprises the drain electrode 21, the source electrode 22, and the gate electrode 23, and the group III-V compound FET 52 comprises the drain electrode 25, the gate electrode 24, and the source electrode 22. In one embodiment, the group III-V compound FET 51 and the group III-V compound FET 52 share the same substrate 201, the same heterojunction structure formed by the GaN layer 203A and the AlGaN layer 204A as shown in FIG. 5, and the same source electrode 22.

The semiconductor device 500 could be configured to receive a driving signal Vdr1 at the gate terminal 503 and receive a driving signal Vdr2 at the gate terminal 504. The drain electrode 25 and the gate electrode 23 are electrically connected to the gate terminal 503, and the driving signal Vdr1 is applied on the gate electrode 23 of the group III-V compound FET 51 and the drain electrode 25 of the group III-V compound FET 52. The driving signal Vdr2 is applied on the gate electrode 24 of the group III-V compound FET 52. In an on condition of the semiconductor device 500, the group III-V compound FET 51 is turned on by the driving signal Vdr1 above its threshold voltage, the group III-V compound FET 52 is turned off by the driving signal Vdr2 below its threshold voltage, and a conduction path is formed between the drain terminal 501 and the source terminal 502 through the group III-V compound FET 51, to allow a current flowing through the semiconductor device 500. In an off condition of the semiconductor device 500, the group III-V compound FET 51 is turned off by the driving signal Vdr1 below its threshold voltage, the group III-V compound FET 52 is turned on by the driving signal Vdr2 above its threshold voltage, the source electrode 22 and the gate electrode 23 of the group III-V compound FET 51 are conducted through the group III-V compound FET 52 locally on the same die. Such that the group III-V compound FET 51 is more insensitive to incorrect turn on conditions such as a negative voltage spike on the source terminal 22 or a positive current spike on the gate terminal 23.

The driving circuit 600 has a driving terminal 601, a driving terminal 602, and a driving return terminal 603. The driving terminal 601 is configured to provide the driving signal Vdr1 to control the group III-V compound FET 51, and the driving terminal 602 is configured to provide the driving signal Vdr2 to control the group III-V compound FET 52, and the driving return terminal 603 is coupled to the source terminal 502 of the semiconductor device 500.

Embodiments of the present invention is to integrate the group III-V compound FET 52 on the same die with the group III-V compound FET 51, to connect the gate electrode 23 with the source electrode 22 of the group III-V compound FET 51 through the group III-V compound FET 52 in an off condition. Thus the group III-V compound FET 51 is pulled down locally on the same die that is more insensitive to incorrect turn on conditions. In one embodiment, the group III-V compound FET 52 could have identical device construction as the group III-V compound FET 51, excepting the possibility to reduce some device layout sizing, such as the layout length Ld2 of the drain electrode 25, the layout length Lg2 of the gate electrode 24, the distance Lgs2 between the source electrode 22 and the gate electrode 24, and the distance Lgd2 between the drain electrode 25 and the gate electrode 24 shown in FIG. 2. No extra mask would be potentially required with relatively small impact on a total die size, since the group III-V compound FET 52 is typically several orders of magnitude smaller conductance and area than the group III-V compound FET 51.

FIG. 6B schematically illustrates a semiconductor device 60 in accordance with an embodiment of the present invention. In one embodiment, the semiconductor device 60 has two dies co-packed together in a chip. As shown in FIG. 6B, the semiconductor 500 is integrated on one die, and a semiconductor 600B is integrated on the other die. The semiconductor device 60 has an input terminal IN, a switching terminal SW, a ground reference terminal GND, and a control terminal PWM. The input terminal IN is configured to receive an input voltage Vin, the switching terminal SW is configured to be alternately connected to the input voltage Vin and the ground reference terminal GND, the control terminal PWM is configured to receive a pulse signal Pul to control the semiconductor device 60.

As shown in FIG. 6B, the semiconductor 600B has a FET device 605 and a control circuit 604. The FET device 605 is connected to the FET device 51 to form a switching node 61 which is connected to the switching terminal SW. In one embodiment, the FET device 605 has a drain terminal 606, a source terminal 607, and a gate terminal 608 configured to receive a driving signal Vdr3. The FET device 605 is connected to the FET device 51 to form a half-bridge switching circuit. In the embodiment shown in FIG. 6B, The drain terminal 606 is connected to the input terminal IN, the source terminal 607 is connected to the drain terminal 501 of the FET device 51 to form the switching node 61, that is the FET device 605 is applied as a high-side switch of the half-bridge switching circuit, and the FET device 51 is applied as a low-side switch of the half-bridge switching circuit. In another embodiment, the FET device 605 could be applied as the low-side switch and the FET device 51 could be applied as the high-side switch.

The control circuit 604 is configured to provide the driving signal Vdr1 to control the FET device 51, the driving signal Vdr2 to control the FET device 52, and the driving signal Vdr3 to control the FET device 605. In one embodiment, the control circuit 604 receives a pulse signal Pul at the control terminal PWM, and providing the driving signal Vdr1-Vdr3 accordingly. For example, when the pulse signal Pul is at a first logic state (e.g., logic high), the driving signal Vdr3 is configured to turn on the FET device 605, the driving signal Vdr2 is configured turn on the FET device 52, and the driving signal Vdr1 is configured to turn off the FET device 51, and when the pulse signal Pul is at a second logic state (e.g., logic low), the driving signal Vdr3 is configured to turn off the FET device 605, the driving signal Vdr2 is configured to turn off the FET device 52, and the driving signal Vdr1 is configured to turn on the FET device 51.

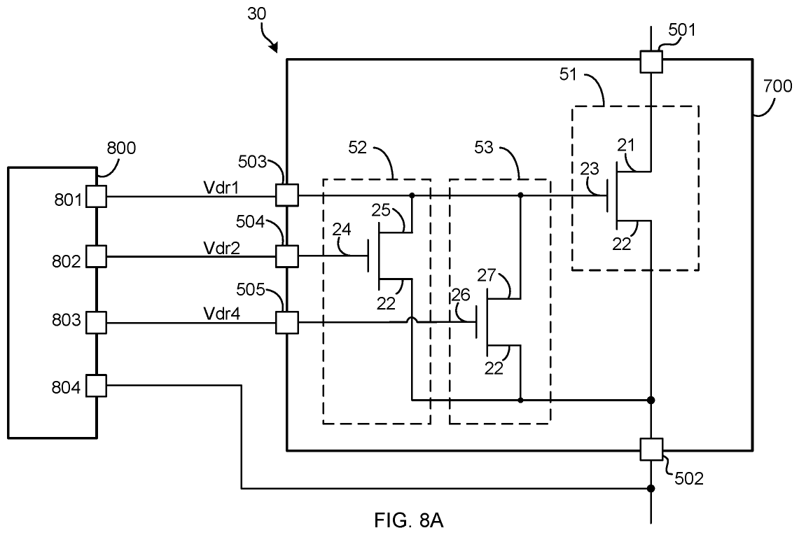

FIG. 7 illustrates a cross-sectional view of a semiconductor device 700 with group III-V compound material in accordance with an embodiment of the present invention. Compared with the semiconductor device 500, the semiconductor device 700 further integrates another group III-V compound FET formed by a gate electrode 26, a drain electrode 27, and the source electrode 22. The gate electrode 26 is electrically connected to a gate terminal 505, and the drain electrode 27 is electrically connected to the gate terminal 503.

In one embodiment, a layout size of the group III-V compound FET comprising the drain electrode 27, the source electrode 22 and the gate electrode 26 is smaller than the layout size of the group III-V compound FET 52. For example, a layout length Lg3 of the gate electrode 26 is less than the layout length Lg2 of the gate electrode 24, a layout length Ld3 of the drain electrode 27 is less than the layout length Ld2 of the drain electrode 25, a distance Lgd3 between the drain electrode 27 and the gate electrode 26 is less than the distance Lgd2 between the drain electrode 25 and the gate electrode 24, and/or a distance Lgs3 between the source electrode 22 and the gate electrode 26 is less than the distance Lgs2 between the source electrode 22 and the gate electrode 24.

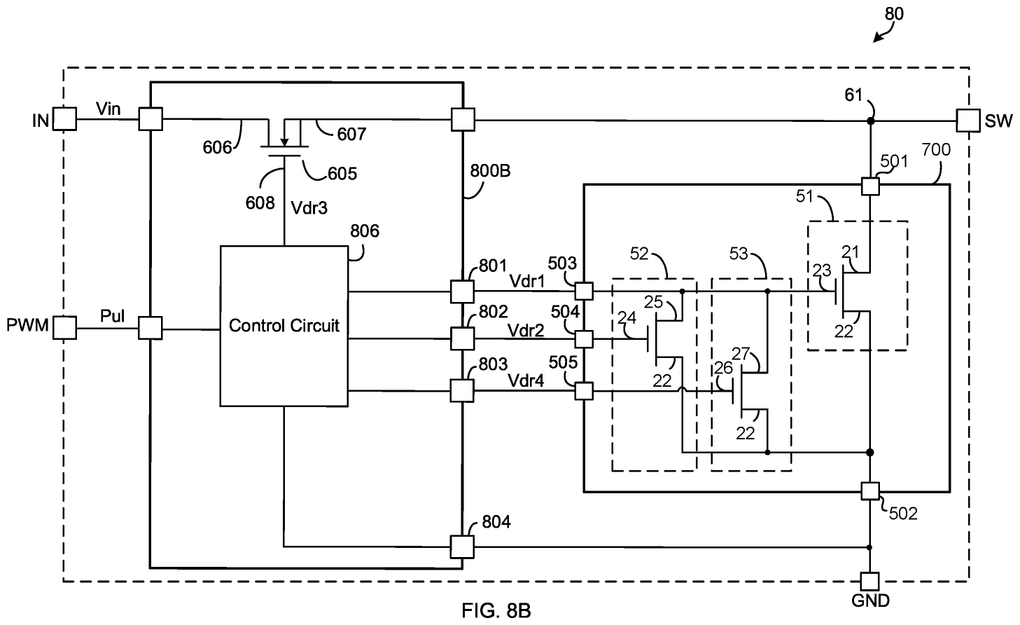

FIG. 8A schematically illustrates a circuit block diagram 30 of the semiconductor device 700 and a driving circuit 800 in accordance with an embodiment of the present invention. Compared with the semiconductor device 500, the semiconductor device 700 further integrates a group III-V compound FET 53 with the group III-V compound FET 51 and the group III-V compound FET 52, sharing the same substrate 201, the same heterojunction structure formed by the GaN layer 203A and the AlGaN layer 204A as shown in FIG. 7, and the same source electrode 22. The group III-V compound FET 53 comprises the drain electrode 27, the source electrode 22, and the gate electrode 26.

The semiconductor device 700 could be further configured to receive a driving signal Vdr4 at the gate terminal 505. The driving signal Vdr4 is applied on the gate electrode 26 of the group III-V compound FET 53. In an on condition of the semiconductor device 700, the group III-V compound FET 51 is turned on by the driving signal Vdr1, the group III-V compound FET 52 is turned off by the driving signal Vdr2, the group III-V compound FET 53 is turned off by the driving signal Vdr4, and the conduction path is formed between the drain terminal 501 and the source terminal 502 through the group III-V compound FET 51, to allow the current flowing through the group III-V compound FET 51. In an off condition of the semiconductor device 700, the group III-V compound FET 51 is turned off by the driving signal Vdr1, at least one of the group III-V compound FET 52 and the group III-V compound FET 53 is turned on by the driving signal Vdr2 and the driving signal Vdr4, the source electrode 22 and the gate electrode 23 of the group III-V compound FET 51 are conducted through at least one of the group III-V compound FET 52 and the group III-V compound FET 53 locally on the same die.

The driving circuit 800 has a driving terminal 801, a driving terminal 802, a driving terminal 803, and a driving return terminal 804. The driving terminal 801 is configured to provide the driving signal Vdr1 to control the group III-V compound FET 51, the driving terminal 802 is configured to provide the driving signal Vdr2 to control the group III-V compound FET 52, the driving terminal 803 is configured to provide the driving signal Vdr4 to control the group III-V compound FET 53, and the driving return terminal 804 is coupled to the source terminal 502 of the semiconductor device 700.

Embodiments of the present invention is to integrate more than one group III-V compound FETs (e.g., 52, 53) on the same die with the group III-V compound FET 51, to connect the gate electrode 23 with the source electrode 22 of the group III-V compound FET 51 through at least one of the group III-V compound FETs in an off condition, such that the pull-down strength of the gate terminal 503 can be adjusted by having multiple integrated pull-down paths.

FIG. 8B schematically illustrates a semiconductor device 80 in accordance with an embodiment of the present invention. In one embodiment, the semiconductor device 80 has two dies co-packed together in a chip. As shown in FIG. 8B, the semiconductor 700 is integrated on one die, and a semiconductor 800B is integrated on the other die. The semiconductor device 80 has the input terminal IN to receive the input voltage Vin, the switching terminal SW, the ground reference terminal GND, and the control terminal PWM to receive the pulse signal Pul to control the semiconductor device 80.

As shown in FIG. 8B, the semiconductor 800B has the FET device 605 and a control circuit 806. The FET device 605 is connected to the FET device 51 to form a switching node 61 which is connected to the switching terminal SW. The control circuit 806 is configured to provide the driving signal Vdr1-Vdr4. In one embodiment, the control circuit 806 receives the pulse signal Pul at the control terminal PWM, and providing the driving signal Vdr1-Vdr4 accordingly. For example, when the pulse signal Pul is at a first logic state (e.g., logic high), the driving signal Vdr3 is configured to turn on the FET device 605, the driving signal Vdr2 is configured turn on the FET device 52, the driving signal Vdr4 is configured turn on the FET device 53, and the driving signal Vdr1 is configured to turn off the FET device 51, and when the pulse signal Pul is at a second logic state (e.g., logic low), the driving signal Vdr3 is configured to turn off the FET device 605, the driving signal Vdr2 is configured to turn off the FET device 52, the driving signal Vdr4 is configured turn off the FET device 53, and the driving signal Vdr1 is configured to turn on the FET device 51.

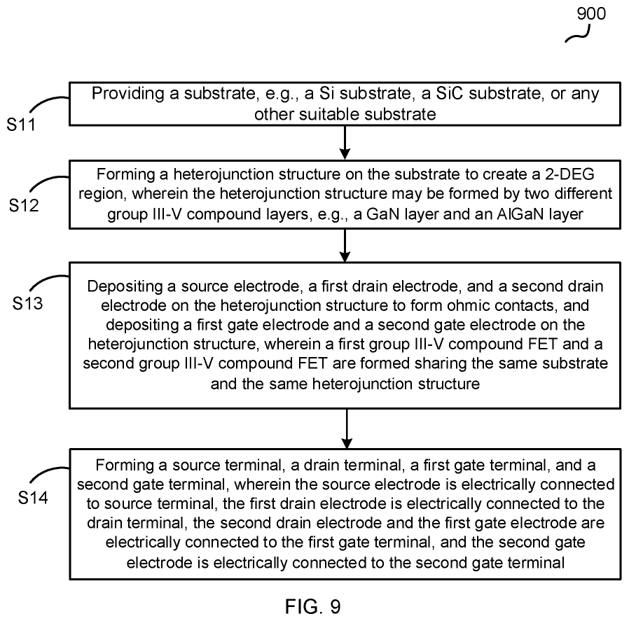

FIG. 9 illustrates a method 900 of forming a semiconductor device in accordance with an embodiment of the present invention. The method 900 has steps S11-S14. The semiconductor device has a first gate terminal, a second gate terminal, a source terminal, and a drain terminal.

At the step S11, providing a substrate, e.g., a Si substrate, a SiC substrate, or any other suitable substrate.

At the step S12, forming a heterojunction structure on the substrate to create a 2-DEG region. The heterojunction structure may be formed by two different group III-V compound layers, e.g., a GaN layer and an AlGaN layer.

At the step S13, depositing a source electrode, a first drain electrode, and a second drain electrode on the heterojunction structure to form ohmic contacts, and depositing a first gate electrode and a second gate electrode on the heterojunction structure, wherein a first group III-V compound FET and a second group III-V compound FET are formed sharing the same substrate and the same heterojunction structure. In one embodiment, a layout size of the second group III-V compound FET is less than a layout size of the first group III-V compound FET.

At the step S14, forming a source terminal, a drain terminal, a first gate terminal, and a second gate terminal, wherein the source electrode is electrically connected to source terminal, the first drain electrode is electrically connected to the drain terminal, the second drain electrode and the first gate electrode are electrically connected to the first gate terminal, and the second gate electrode is electrically connected to the second gate terminal.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

I/We claim:

1. A semiconductor device, comprising:
a substrate;
a heterojunction structure formed by a first group III-V compound layer and a second group III-V compound layer above the substrate;
a first gate electrode deposited above the first group III-V compound layer and the second group III-V compound layer, the first gate electrode is electrically connected to a first gate terminal;
a second gate electrode deposited above the first group III-V compound layer and the second group III-V compound layer, the second gate electrode is electrically connected to a second gate terminal;
a source electrode deposited above the heterojunction structure, the source electrode is electrically connected to a source terminal;
a first drain electrode deposited above the heterojunction structure, the first drain electrode is electrically connected to a drain terminal; and
a second drain electrode deposited above the heterojunction structure, the second drain electrode is electrically connected to the first gate terminal; wherein
the first gate electrode is positioned between the source electrode and the first drain electrode, and the second gate electrode is positioned between the source electrode and the second drain electrode.

2. The semiconductor device of claim 1, wherein a two-dimension electron gas (2-DEG) region is formed at a transition between the first group III-V compound layer and the second group III-V compound layer, and wherein the source electrode, the first drain electrode, and the second drain electrode are configured to make contact to the 2-DEG region to form ohmic contacts.

3. The semiconductor device of claim 1, wherein the first group III-V compound layer comprises a GaN layer, and the second group III-V compound layer comprises an AlGaN layer.

4. The semiconductor device of claim 1, wherein a length of the second gate electrode is less than a length of the first gate electrode, and a length of the second drain electrode is less than a length a the first drain electrode.

5. The semiconductor device of claim 1, wherein a distance between the second drain electrode and the second gate electrode is less than a distance between the first drain electrode and the first gate electrode.

6. The semiconductor device of claim 1, wherein a distance between the source electrode and the second gate electrode is less than a distance between the source electrode and the first gate electrode.

7. The semiconductor device of claim 1, further comprising:
an AlN nucleation layer positioned between the substrate and the heterojunction structure, to epitaxially grow the first group III-V compound layer and the second group III-V compound layer.

8. The semiconductor device of claim 1, further comprising:
a third gate electrode deposited above the first group III-V compound layer and the second group III-V compound layer, the third gate electrode is electrically connected to a third gate terminal; and
a third drain electrode deposited above the heterojunction structure, the third drain electrode is electrically connected to the first gate terminal.

9. The semiconductor device of claim 8, wherein at least one of the following relationships is satisfied:
(1) a length of the third gate electrode is less than a length of the second gate electrode, and the length of the second gate electrode is less than a length of the first gate electrode;
(2) a length of the third drain electrode is less than a length of the second drain electrode, and the length of the second drain electrode is less than a length of the first drain electrode;
(3) a distance between the third drain electrode and the third gate electrode is less than a distance between the second drain electrode and the second gate electrode, and the distance between the second drain electrode and the second gate electrode is less than a distance between the first drain electrode and the first gate electrode; and
(4) a distance between the source electrode and the third gate electrode is less than a distance between the source electrode and the second gate electrode, and the distance between the source electrode and the second gate electrode is less than a distance between the source electrode and the first gate electrode.

10. A semiconductor device, comprising:
a substrate;
a GaN layer epitaxially growing above the substrate;
an AlGaN layer epitaxially growing above the GaN layer, to create a heterojunction structure;
a first gate electrode and a second gate electrode deposited above the AlGaN layer, wherein a length of the second gate electrode is less than a length of the first gate electrode;
a source electrode, a first drain electrode and a second drain electrode deposited above the GaN layer; wherein
the first gate electrode is positioned between the source electrode and the first drain electrode, the second gate electrode is positioned between the source electrode and the second drain electrode, and the second drain electrode is electrically connected to the first gate electrode.

11. The semiconductor device of claim 10, wherein a first FET comprising the source electrode, the first drain electrode, and the first gate electrode is controlled ON and OFF in response to a first driving signal applied to the first gate electrode, and a second FET comprising the source electrode, the second drain electrode, and the second gate electrode is controlled ON and OFF in response to a second driving signal applied to the second gate electrode.

12. The semiconductor device of claim 10, further comprising:
a third drain electrode deposited above the GaN layer, the third drain electrode is electrically connected to the first gate electrode;
a third gate electrode deposited above the AlGaN layer, the third gate electrode is positioned between the source electrode and the third drain electrode.

13. The semiconductor device of claim 12, wherein at least one of the following relationships is satisfied:
(1) a length of the third gate electrode is less than a length of the second gate electrode, and the length of the second gate electrode is less than a length of the first gate electrode;
(2) a length of the third drain electrode is less than a length of the second drain electrode, and the length of the second drain electrode is less than a length of the first drain electrode;
(3) a distance between the third drain electrode and the third gate electrode is less than a distance between the second drain electrode and the second gate electrode, and the distance between the second drain electrode and the second gate electrode is less than a distance between the first drain electrode and the first gate electrode; and
(4) a distance between the source electrode and the third gate electrode is less than a distance between the source electrode and the second gate electrode, and the distance between the source electrode and the second gate electrode is less than a distance between the source electrode and the first gate electrode.

14. The semiconductor device of claim 10, wherein at least one of the following relationships is satisfied:
(1) a distance between the second drain electrode and the second gate electrode is less than a distance between the first drain electrode and the first gate electrode;
(2) a distance between the source electrode and the second gate electrode is less than a distance between the source electrode and the first gate electrode; and
(3) a length of the second drain electrode is less than a length a the first drain electrode.

15. The semiconductor device of claim 10, further comprising:
a source terminal, electrically connected to the source electrode;
a drain terminal, electrically connected to the first drain electrode;
a first gate terminal, electrically connected to the first gate electrode and the second drain electrode, wherein the first gate terminal is configured to receive a first driving signal; and
a second gate terminal, electrically connected to the second gate electrode, wherein the second gate terminal is configured to receive a second driving signal, and the semiconductor device is controlled by the first driving signal and the second driving signal.

16. A semiconductor device, comprising:
a first die, having a substrate, a heterojunction structure formed by two group III-V compound layers on the substrate, a first field effect transistor (FET) device and a second FET device formed on the substrate; wherein
the first FET device having a source electrode and a first drain electrode deposited above the heterojunction structure, and a first gate electrode deposited above the two group III-V compound layers; and
the second FET device having the source electrode shared with the first FET device, a second drain electrode deposited above the heterojunction structure, and a second gate electrode deposited above the two group III-V compound layers; and wherein
the second drain electrode is electrically connected to the first gate electrode.

17. The semiconductor device of claim 16, further comprising:
a second die co-packed with the first die in a chip, the second die having a third FET device and a control circuit; wherein
the third FET device is connected to the first FET device to form a switching node; and wherein
the control circuit is configured to provide a first driving signal to control the first FET device, a second driving signal to control the second FET device, and a third driving signal to control the third FET device.

18. The semiconductor device of claim 16, further comprising:
a first gate terminal configured to receive a first driving signal, the first gate electrode and the second drain electrode are electrically connected to the first gate terminal;
a second gate terminal configured to receive a second driving signal, the second gate electrode is electrically connected to the second gate terminal;
a drain terminal, the first drain electrode is electrically connected to the drain terminal; and
a source terminal, the source electrode is electrically connected to the source terminal.

19. The semiconductor device of claim 18, wherein:
when turning on the first FET device by the first driving signal and turning off the second FET device by the second driving signal, the drain terminal and the source terminal are conducted through the first FET device; and
when turning off the first FET device by the first driving signal and turning on the second FET device by the second driving signal, the first gate terminal and the source terminal are conducted through the second FET device.

20. The semiconductor device of claim 16, wherein a layout size of the second FET device is less than a layout size of the first FET device.
